(19) United States
(12) Patent Application Publication
(10) Pub. No.: US 2026/0122864 A1
(43) Pub. Date: Apr. 30, 2026

(54) POWER INVERTER MODULE WITH MOLDED HOUSING

(71) Applicant: GM GLOBAL TECHNOLOGY OPERATIONS LLC, Detroit, MI (US)

(72) Inventors: Selina X. Zhao, Rochester Hills, MI (US); Muhammad A. Zahid, Troy, MI (US); Yilun Luo, Ann Arbor, MI (US); Ajay Mehta, Auburn Hills, MI (US); Khorshed Mohammed Alam, Canton, MI (US); Roshan Kandanda, Sterling Heights, MI (US); Anthony M. Coppola, Rochester Hills, MI (US)

(73) Assignee: GM GLOBAL TECHNOLOGY OPERATIONS LLC, Detroit, MI (US)

(21) Appl. No.: 18/930,136

(22) Filed: Oct. 29, 2024

(51) Int. Cl. H05K 7/20; B60L 55/00

(52) U.S. Cl. CPC H05K 7/20927; H05K 7/20254; H05K 7/20272; B60L 55/00

(57) ABSTRACT

An assembly includes a housing comprised of a molded composite material that at least partially defines an internal cavity and a coolant block fixed relative to the housing. The coolant block includes a switch engagement surface facing into the internal cavity and at least one internal cooling passage extending between a cooling fluid inlet and a cooling fluid outlet. The assembly also includes semiconductor switches located within the housing and in direct thermal engagement with the switch engagement surface on the coolant block and the semiconductor switches are in electrical communication with alternating current bus bars. The assembly also includes a direct current link capacitor located within the internal cavity and in electrical communication with the semiconductor switches.

### INTRODUCTION

This disclosure relates to power inverters modules, and more particularly, to power inverter modules having molded housings.

Fully electric or hybrid electric vehicles have achieved greater range through advancements in battery technology. Certain batteries, such as traction batteries, provide power in the form of direct current (“DC”). The DC power from the traction battery is converted to alternative current (“AC”) by a power module to drive a traction motor or to provide power to other portions of the vehicle. As the traction batteries store large amounts of DC power, utilizing a portion of that power for purposes other than vehicle propulsion is beneficial. For example, a user of the vehicle may want to use the traction battery to power electronic devices when in remote areas, to power to a home during a power outage, or to provide power directly to a power grid. In one example, to convert the DC power from the traction battery to AC power that is utilized by other sources, a second power module is linked to the traction battery separate from the power module used to drive the traction motor.

### SUMMARY

Disclosed herein is an assembly. The assembly includes a housing comprised of a molded composite material that at least partially defines an internal cavity and a coolant block fixed relative to the housing. The coolant block includes a switch engagement surface facing into the internal cavity and at least one internal cooling passage extending between a cooling fluid inlet and a cooling fluid outlet. The assembly also includes semiconductor switches located within the housing and in direct thermal engagement with the switch engagement surface on the coolant block and the semiconductor switches are in electrical communication with alternating current bus bars. The assembly also includes a direct current link capacitor located within the internal cavity and in electrical communication with the semiconductor switches.

In one aspect of the disclosure the assembly includes a pair of high-voltage direct current bus bars in electrical communication with the direct current link capacitor and a high-voltage direct current connector integrally formed into the housing.

In one aspect of the disclosure the assembly includes at least one of a control board or a gate driver board located within the internal cavity and in electrical communication with a communications connector integrally formed into the housing and the plurality of semiconductor switches.

In one aspect of the disclosure the assembly includes a thermally conductive material located between the plurality of semiconductor switches and the coolant block.

In one aspect of the disclosure the housing includes an internal dividing wall at least partially separating the direct current link capacitor from the plurality of semiconductor switches and the direct current link capacitor is at least partially co-molded with the housing.

In one aspect of the disclosure the internal dividing wall includes a heat transfer feature embedded within the internal dividing wall and the heat transfer feature is in direct thermal engagement with the coolant block.

In one aspect of the disclosure a first direct current bus bar is in electrical communication with a first set of the plurality of semiconductor switches and a second direct current bus bar is in electrical communication with a second set of the plurality of semiconductor switches.

In one aspect of the disclosure the assembly includes a choke located within the internal cavity and defining a central opening that surrounds the plurality of alternating current bus bars in electrical communication with the plurality of semiconductor switches.

In one aspect of the disclosure the choke is over molded with the housing and includes a nanocrystalline material that forms a loop and surrounds the plurality of alternating current bus bars.

In one aspect of the disclosure the coolant block is comprised of a first material and the housing is comprised of a second material different from the first material and the housing at least partially surrounds a perimeter of the coolant block.

In one aspect of the disclosure coolant block includes internal cooling passages that are at least partially defined by the housing and a thermally conductive lid and the thermally conductive lid is in direct thermal contact with the plurality of semiconductor switches.

In one aspect of the disclosure the thermally conductive lid includes a plurality of heat transfer features extending therefrom that at least partially define the internal cooling passages.

Disclosed herein is a method of forming a power inverter module. The method includes forming a housing for the power inverter module at least partially defining an internal cavity. A coolant block is at least partially fixed relative to the housing while forming the housing and the coolant block includes a switch engagement surface facing into the internal cavity with at least one internal cooling passage extending between a cooling fluid inlet and a cooling fluid outlet. The method also includes attaching semiconductor switches in direct thermal engagement with the coolant block and installing a direct current link capacitor in the internal cavity of the housing. The semiconductor switches are in electrical communication with the direct current link capacitor and alternating current bus bars.

In one aspect of the disclosure forming the housing includes forming a high-voltage direct current connector integrally into the housing for interfacing with high-voltage direct current bus bars in electrical communication with the direct current link capacitor and the direct current link capacitor is at least partially co-molded with the housing.

In one aspect of the disclosure forming the housing includes forming a choke having a nanocrystalline material that surrounds the plurality of alternating current bus bars integrally with the housing.

In one aspect of the disclosure the at least one internal cooling passage is spaced from the housing by a body portion of the coolant block.

In one aspect of the disclosure the at least one internal cooling passage is at least partially defined by the housing and a thermally conductive lid and the thermally conductive lid is in direct thermal contact with the plurality of semiconductor switches.

Disclosed herein is a vehicle. The vehicle includes a vehicle body supported by wheels, a traction battery fixed relative to the vehicle body, a traction motor in driving engagement with at least one of the wheels, and a power inverter module electrically connecting the traction battery with the traction motor for selecting driving the at least one of the wheels. The power inverter module includes a housing comprised of a molded composite material that at least partially defines an internal cavity and a coolant block fixed relative to the housing. The coolant block includes a switch engagement surface facing into the internal cavity and at least one internal cooling passage extending between a cooling fluid inlet and a cooling fluid outlet. The assembly also includes semiconductor switches located within the housing and in direct thermal engagement with the switch engagement surface on the coolant block and the semiconductor switches are in electrical communication with alternating current bus bars. The assembly also includes a direct current link capacitor located within the internal cavity and in electrical communication with the semiconductor switches.

In one aspect of the disclosure the assembly includes a pair of high-voltage direct current bus bars in electrical communication with the direct current link capacitor and a high-voltage direct current connector integrally formed into the housing with the direct current link capacitor at least partially co-molded with the housing.

In one aspect of the disclosure the assembly includes at least one of a control board or a gate driver board located within the internal cavity and in electrical communication with a communications connector integrally formed into the housing and the plurality of semiconductor switches.

### BRIEF DESCRIPTION OF THE DRAWINGS

The accompanying drawings, which are incorporated into and constitute a part of this specification, illustrate implementations of the disclosure and together with the description, explain the principles of the disclosure.

FIG. 1 is a plan view illustration of a vehicle, and a battery system coupled to an Electronic Control Unit (ECU) and a power inverter module (PIM) in which the principles of the present disclosure may be implemented.

FIG. 2 is a perspective view of the PIM of FIG. 1.

FIG. 3 is a cross-sectional view taken along line 3-3 of FIG. 2 illustrating an example coolant block.

FIG. 4 is a bottom view of the PIM of FIG. 1.

FIG. 5 is a schematic illustration of another example of a coolant block for use in the PIM of FIG. 1.

FIG. 6 is a schematic illustration of a fluid flow path through the coolant block of FIG. 5.

FIG. 7 is a schematic illustration of yet another example of a coolant block for use in the PIM of FIG. 1.

FIG. 8 is a schematic illustration of a fluid flow path through the coolant block of FIG. 7.

FIG. 9 is a flow chart of an example method of forming the PIM of FIG. 1.

### DETAILED DESCRIPTION

The present disclosure is susceptible of embodiment in many different forms. Representative examples of the disclosure are shown in the drawings and described herein in detail as non-limiting examples of the disclosed principles. To that end, elements and limitations described in the Abstract, Introduction, Summary, and Detailed Description sections, but not explicitly set forth in the claims, should not be incorporated into the claims, singly or collectively, by implication, inference, or otherwise.

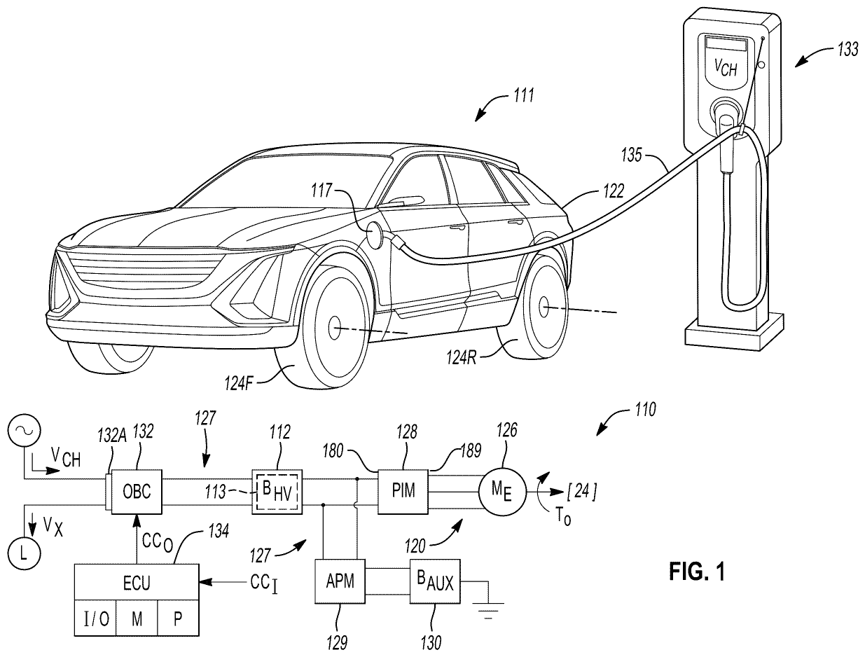

While the principles of the present disclosure have wide application to diverse architectures, for purposes of example, electric vehicles are considered. To that end, FIG. 1 is a plan view illustration of a vehicle and a battery system coupled to an Electronic Control Unit (ECU) for controlling various operations of the vehicle and a power inverter module (PIM) in which the principles of the present disclosure may be implemented. One feature of the PIM of this disclosure is a reduction in part count and complexity of assembly by utilizing a molded housing for the PIM that integrates various components of the PIM as discussed in greater detail below.

While an electric vehicle 111 (“EV”) is shown in FIG. 1, it will be appreciated that the disclosure is not so limited to a vehicle having the appropriate programmed circuitry. FIG. 1 shows one such example. FIG. 1 depicts an electrified powertrain system 110 having a high-voltage battery pack (B_{HV}) 112. In a non-limiting example, the battery pack 112 may be embodied as a high-capacity battery having a voltage capability of about 400-800 volts or more, with the actual voltage capability of the battery pack 112 provided based on a desired operating/state of charge (“SOC”) range, gross weight, and power rating of a load connected to the battery pack 112. In a possible construction, the battery pack 112 may be a propulsion battery pack generally composed of an array of lithium-ion or lithium-ion polymer rechargeable electrochemical battery cells, which may be a cylindrical battery cell. The present teachings may also be applied to prismatic battery cells, and to pouch-style battery cells in possible configurations, and thus the cylindrical battery cell is exemplary without being limiting.

Although internal details of the battery cells in battery pack 112 are omitted for illustrative simplicity, those skilled in the art will appreciate that the battery cells contain within the cell cavity an electrolyte material, working electrodes in the form of a cathode and an anode, and a permeable separator (not shown), which are collectively enclosed inside an electrically insulated can or casing. Grouped battery cells may be connected in series or parallel through use of an electrical interconnect board and related buses, sensing hardware, and power electronics (not shown but well understood in the art). An application-specific number of the battery cells in battery pack 112 may be arranged relative to the battery tray 113 in columns and rows. In a nominal “xyz” Cartesian reference frame, for instance, the battery tray 113 when viewed from above or below may have a length (x-dimension) and a width (y-direction), with a height (z-dimension) extending in an orthogonal direction away from the battery tray 113.

In a representative use case, the electrified powertrain system 110 may be used as part of the EV 111 or another mobile system. As shown, the EV 111 may be embodied as a battery electric vehicle, with the present teachings also being extendable to plug-in hybrid electric vehicles. Alternatively, the electrified powertrain system 110 may be used as part of another mobile system such as but not limited to a rail vehicle, aircraft, marine vessel, robot, farm equipment, etc. Likewise, the electrified powertrain system 110 may be stationary, such as in the case of a powerplant, hoist, drive belt, or conveyor system. Therefore, the electrified powertrain system 110 in the representative vehicular embodiment of FIG. 1 is intended to be illustrative of the present teachings and not limiting thereof.

The EV 111 shown in FIG. 1 includes a vehicle body 122. The vehicle body 122 may include a frame within the vehicle body 122 to define areas for placement of mechanical and electrical components, as well as a passenger cabin. The EV may further include road wheels 124F and 124R, with “F” and “R” indicating the respective front and rear positions. The road wheels 124F and 124R rotate about respective axes, with the road wheels 124F, the road wheels 124R, or both being powered by output torque (arrow T_{O}) from a rotary electric machine (M_{E}) 126 of the electrified powertrain system 110 as indicated by arrow [24]. The road wheels 124F and 124R thus represent a mechanical load in this embodiment, with other possible mechanical loads being possible in different host systems. To that end, the electrified powertrain system 110 includes a power inverter module (PIM) 128 (also referenced herein as a power module (PM)) and the high-voltage battery pack 112, e.g., a multi-cell lithium-ion propulsion battery or a battery having another application-suitable chemistry, both of which are arranged on a high-voltage DC bus 127. As appreciated in the art, the PIM 128 includes a DC side (180) and an alternating current (AC) side 189, with the latter being connected to individual phase windings (not shown) of the rotary electric machine 126 when the rotary electric machine 126 is configured as a polyphase rotary electric machine in the form of a propulsion or traction motor as shown.

The battery pack 112 of FIG. 1 in turn is connected to the DC side 180 of the PIM 128, such that a battery voltage from the battery pack 112 is provided to the power inverter module (PIM) 128 during propulsion modes of the EV 111. The PIM 128, or more precisely a set of semiconductor switches (not shown) residing therein, are controlled via pulse width modulation (PWM), pulse density modulation (PDM), or other suitable switching control techniques to invert a DC input voltage on the DC bus 127 into an AC output voltage suitable for energizing a high-voltage AC bus 120. As noted, the PIM 128 may also be referred to simply as a power module (PM), which may include an inverter or converter. High-speed switching of the resident semiconductor switches of the PIM 128 energizes the rotary electric machine 126 to thereby cause the rotary electric machine 126 to deliver the output torque (arrow T_{O}) as a motor drive torque to one or more of the road wheels 124F and/or 124R in another coupled mechanical load in other implementations.

Electrical components of the electrified powertrain system 110 may also include an accessory power module (APM) 129 and an auxiliary battery (B_{AUX}) 130. The APM 129 is configured as a DC-DC converter that is connected to the DC bus 127, as appreciated in the art. In operation, the APM 129 is capable, via internal switching and voltage transformation, of reducing a voltage level on the DC bus 127 to a lower level suitable for charging the auxiliary battery 130 and/or supplying low-voltage power to one or more accessories (not shown) such as lights, displays, etc. Thus, “high-voltage” refers to voltage levels well in excess of typical 12-15V low/auxiliary voltage levels, with 400V or more being an exemplary high-voltage level in some embodiments of the battery pack 112.

In some configurations, the electrified powertrain system 110 of FIG. 1 may include an on-board charger (OBC) 132 that is selectively connectable to an offboard charging station 133 via an input/output (I/O) block 132A during a charging mode during which the battery pack 112 is recharged by an AC charging voltage (V_{CH}) from the offboard charging station 133. The I/O block 132A is connectable to a charging port 117 on the vehicle body 122. For instance, a charging cable 135 may be connected to the charging port 117, e.g., via an SAE J1772 connection. The electrified powertrain system 110 may also be configured to selectively receive a DC charging voltage in one or more embodiments as appreciated in the art, in which case the OBC 132 would be selectively bypassed using circuitry (not shown), e.g., that may be used to charge and/or discharge the battery pack 112 gradually for performing various functions, such as testing the SOC. The OBC 132 could also operate in different modes, including a charging mode during which the OBC 132 receives the AC charging voltage (V_{CH}) from the offboard charging station 133 to recharge the battery pack 112 after a low charge indicator light displays on the dashboard, and a discharging mode, represented by arrow V_{X}, during which the OBC 132 offloads power from the battery pack 112 to an external AC electrical load (L). In this manner, the OBC 132 may embody a bidirectional charger.

Still referring to FIG. 1, the electrified powertrain system 110 may also include an electronic control unit (ECU) 134. The ECU 134 is operable for regulating ongoing operation of the electrified powertrain system 110 via transmission of electronic control signals (arrow CC_{O}). The ECU 134 does so in response to electronic input signals (arrow CC_{I}). Such input signals (arrow CC_{I}) may be actively communicated or passively detected in different embodiments, such that the ECU 134 is operable for determining a particular mode of operation. In response, the ECU 134 controls operation of the electrified powertrain system 110. Thus, the ECU and its accompanying components may act as a BMS for performing functions including estimating the SOC, etc.

To that end, the ECU 134 may be equipped with one or more processors (P), e.g., logic circuits, combinational logic circuit(s), Application Specific Integrated Circuit(s) (ASIC), electronic circuit(s), central processing unit(s), semiconductor IC devices, etc., as well as input/output (I/O) circuit(s), appropriate signal conditioning and buffer circuitry, and other components such as a high-speed clock to provide the described SOC functionality in prior figures, as well as different functions identified by the CC input signal. The ECU 134 also includes an associated non-transitory computer-readable storage medium, i.e., memory (M) inclusive of read only, programmable read only, random access, a hard drive, etc., whether resident, remote or a combination of both. Control routines, including code for executing the SOC model with hysteresis, are executed by the processor to monitor relevant inputs from sensing devices and other networked control modules (not shown), and to execute control and diagnostic routines to govern operation of the electrified powertrain system 110. The I/O circuits may be directly coupled to the ECU 134, along with memory M and one or more processors P for executing code that estimates SOC. In an aspect, the BMS system may collectively be realized as ECU 134, OBC 132 and DC bus 127. OBC 132 and DC bus 127 may be an apparatus within the BMS or included as part of the BMS that is enabled to be connected to the outer terminals of battery pack 112 to perform the functions recited herein. In some implementations, the BMS may be coupled directly with the battery pack.

EV 111 may, like other vehicles, include a dashboard implanted within or otherwise connected to the body of EV 111. The body houses a cabin where the driver and occupants reside. The apparatus discussed above may include control signals to the dashboard and conversion circuitry to enable the driver to assess the SOC remaining based on an amount or percentage of charge remaining, an estimated time that the vehicle will die or imminently needs recharging, and other data. At least some of these aspects may be computed by the BMS, including ECU 134 and its associated processor P running code from memory M. Messages may be sent via the I/O circuit to other parts of the vehicle, via CC_{O} or another connection not specifically shown.

In the above example, the PIM 128 (or more simply, the PM) may include a set of semiconductor switches driven by a modulation technique such as PWM (although other suitable modulation techniques such as PDM may be used). In other configurations, the ECU or a microcontroller unit (MCU) therein (e.g., processor P) may also be used to govern the transmission of modulated signals. The semiconductor switches of PIM 128 may include power transistors, and the modulation technique used to drive them may include intermediary circuitry to suitably decode the PWM signals where needed and to adjust the rail-to-rail voltage swing from power used by logic circuits (e.g., 0 to 5 volts, or the like) to the higher voltages needed by a gate driver to switch the power transistors that drive the rotary electric machine 126. With reference to the PIM 128, a gate driver may be employed to turn the power transistors/switches on and off.

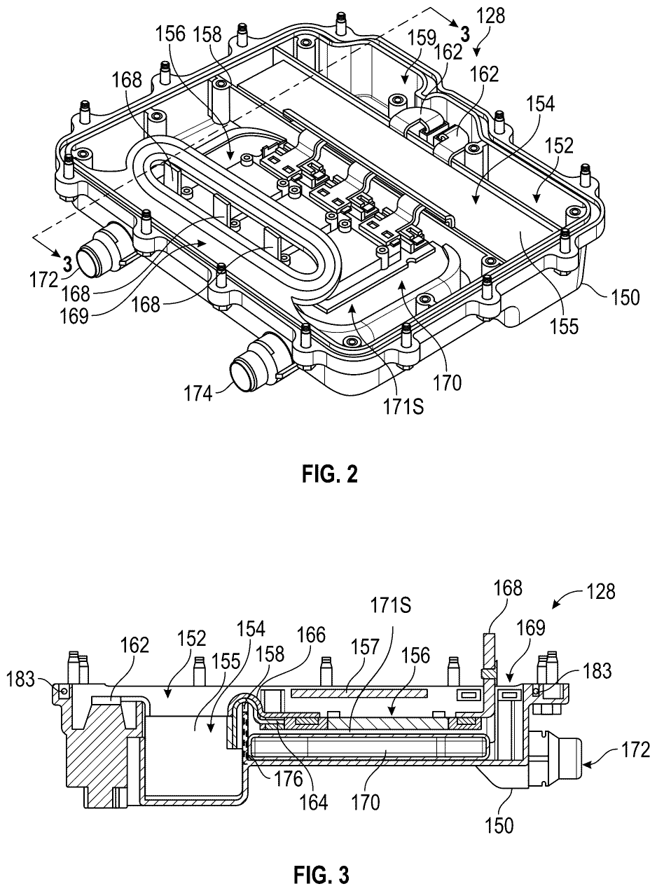

As shown in FIGS. 2-4, the PIM 128 includes a housing 150, such as a housing molded from a composite material, that at least partially defines an internal cavity 152. The internal cavity 152 includes a first portion for accepting a DC link capacitor 154 and a second portion for accepting semiconductor switches 156. In the illustrated example, the first portion is at least partially separated from the second portion by an internal dividing wall 158. In the illustrated example, the internal dividing wall 158 is integrally formed with the housing 150.

In one example, the composite material used to form the housing 150 can include a woven fibrous mat or chopped fibers that are over molded into the housing 150 for improved structural rigidity. The fibers can include at least one of glass fibers, carbon fibers, metallic fibers, or metal coated glass fibers. Furthermore, the composite material can include a thermoset polymeric resins system that has a glass transition temperature greater than 300 degrees Celsius, a coefficient of thermal expansion ranging from 20-25 ppm/C, a dielectric strength greater than or equal to 5 kV/mm, and a moisture absorption of less than 0.5% by mass.

In one example, the thermoset polymeric resins are such but not limited to benzoxazine, a bis-maleimide (BMI), a cyanate ester, an epoxy, a phenolic (PF), a polyacrylate (acrylic), a polyimide (PI), an unsaturated polyester, a polyurethane (PU), a vinyl ester, a siloxane, co-polymers thereof, and combinations thereof.

In another example, the thermoplastic polymeric resins are such but not limited from polyethyleneimine (PEI), polypropylene (PP), polycarbonate/acrylonitrile butadiene styrene (PC/ABS), high-density polyethylene (HDPE), polyethylene terephthalate (PET), poly(methyl methacrylate) (PMMA), polycarbonate (PC), polyaryletherketone (PAEK), polyetherketoneketone (PEKK), polyamide-imide (PAI), polyamide (PA) (e.g., nylon 6, nylon 66, nylon 12), polyetheretherketone (PEEK), polyetherketone (PEK), a polyphenylene sulfide (PPS), a thermoplastic polyurethane (TPU), co-polymers thereof, and combinations thereof.

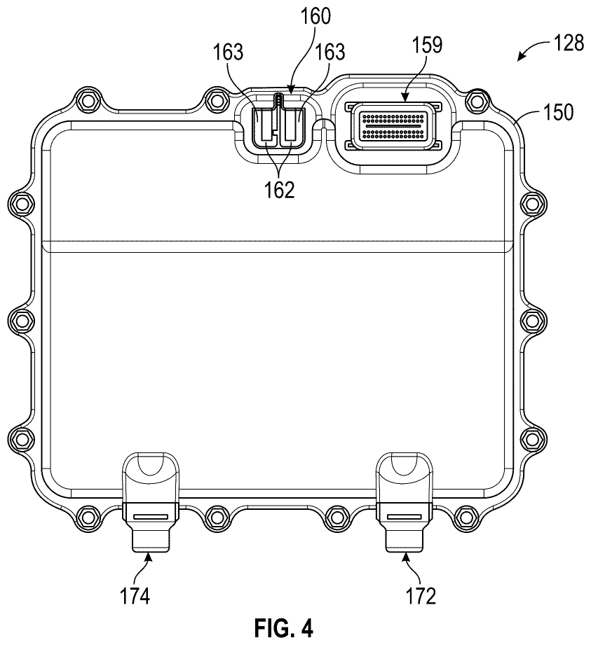

In the example illustrated in FIG. 4, the DC link capacitor 154 is in electrical communication with a high-voltage DC connector 160 integrally formed into the housing 150, such as by an over molding process when forming the housing 150. The DC link capacitor 154 can also be at least partially co-molded with the housing 150. One feature of having the high-voltage DC connector 160 integrally formed into the housing 150 is that it eliminates part count and assembly steps for the PIM 128. A pair of high-voltage DC bus bars 162 form an electrical connection between the high-voltage DC connector 160 and the DC link capacitor 154. The pair of high-voltage DC bus bars 162 are electrically isolated from each other due to the non-conductive material selected for forming the housing 150 in addition to the potting material 155 placed within the first portion of the internal cavity 152 that enclosing the DC link capacitor 154. The potting material 155 also improves noise, vibration, and harshness (“NVH”) for the PIM 128 during operation of the EV 111. In the illustrated example, the pair of high-voltage DC bus bars 162 interface with the high-voltage DC connector 160 by extending through a pair of corresponding passageways 163 at least partially defined by the housing 150 to form the electrical connection with the battery pack 112.

The semiconductor switches 156 includes a first set of switches, such as high switches, and a second set of switches, such as low switches, for converting the DC power from the battery pack 112 to AC power in AC bus bars 168 for use by the rotary electric machine 126. In the illustrated example, the AC bus bars 168 pass through a choke 169 that is integrally formed into the housing 150. The AC choke 169 can be integrally formed into the housing 150 by an over molding process that encloses a nanocrystalline material when forming the housing 150. The AC choke 169 operates in an AC circuit by limiting a rate of change over a specified frequency range, while allowing passage of lower frequency AC in the circuit. Furthermore, the choke 169 is at least partially located in the internal cavity 152 and integrally forming the choke 169 can improve both active and passive cooling of the choke 169 by absorbing heat through the cooling fluid as discussed in greater detail below. The choke 169 can be a linear choke or a triangular choke depending on the desired application and packaging.

The semiconductor switches 156 are in electrical communication with a control/gate driver board 157 (FIG. 3) that directions operation of the semiconductor switches 156 for creating an alternating current in AC bus bars 168. The control/gate driver board 157 is in electrical communication with a communications connector 159 that is integrally formed into the housing 150. One feature of integrally forming the communications connector 159 into the housing 150 is the elimination of additional components and assembly steps for the PIM 128. The control/gate driver board 157 can then receive communications from the ECU 134 that are transformed into corresponding signals for operating the semiconductor switches 156. While the illustrated example shows the control/gate driver board 157 as a single unit, it can be separated into a separate control board and gate driver board.

The DC link capacitor 154 is connectable to the first set of switches through a first DC bus bar 164 and the DC link capacitor is connectable to the second set of switches through a second DC bus bar 166. In the illustrated example, the first and second DC bus bars 164, 166 are electrically isolated from each other and located adjacent to the internal dividing wall 158. As discussed in greater detail below, the internal dividing wall 158 can improve heat transfer from the first and second DC bus bars 164, 166 and the DC link capacitor into cooling fluid traveling through the PIM 128.

As shown in FIGS. 2-3, the semiconductor switches 156 are located adjacent to and in direct thermal engagement or contact with a switch engagement surface 171S on a coolant block 170. In the illustrated example, the coolant block 170 is over-molded with the housing 150. One feature of over molding the coolant block 170 with the housing 150 is the elimination of fasteners for securing the coolant block 170 to the housing 150 and a reduction in assembly steps. An outer facing surface of the coolant block 170 that faces away from the internal cavity 152 is enclosed by the housing 150 with at least a portion of a perimeter and internally facing surface of the coolant block 170 also being enclosed by the housing 150. In the illustrated example shown in FIGS. 2-4, the coolant block 170 includes a cooling fluid inlet 172 and a cooling fluid outlet 174 that are in fluid communication with internal cooling passages defined by the coolant block 170 to allow for cooling fluid to absorb and transfer heat generated by the semiconductor switches 156 and other heat generating components away from the PIM 128. As shown in FIGS. 2-4, the internal cooling passages are separated from the housing 150 by a body portion of the coolant block 170.

Furthermore, because the coolant block 170 is over-molded with the housing 150, a heat transfer feature 176, such as a metallic fin (shown in dashed lines in FIG. 3), may be integrally formed with the coolant block 170 and embedded within the internal dividing wall 158 to further facilitate the removal of heat generated by the first and second DC bus bars 164, 166 and the DC link capacitor 154. While the illustrated example of FIGS. 2-4 shows the coolant block 170 defining the entirety of the internal cooling passages, the coolant block may be formed from multiple components as described in greater detail below. Furthermore, the coolant block 170 can provide structural rigidity to the housing 150.

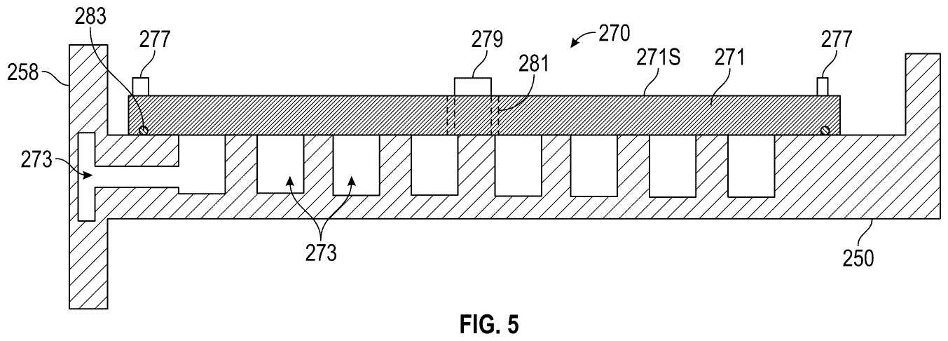

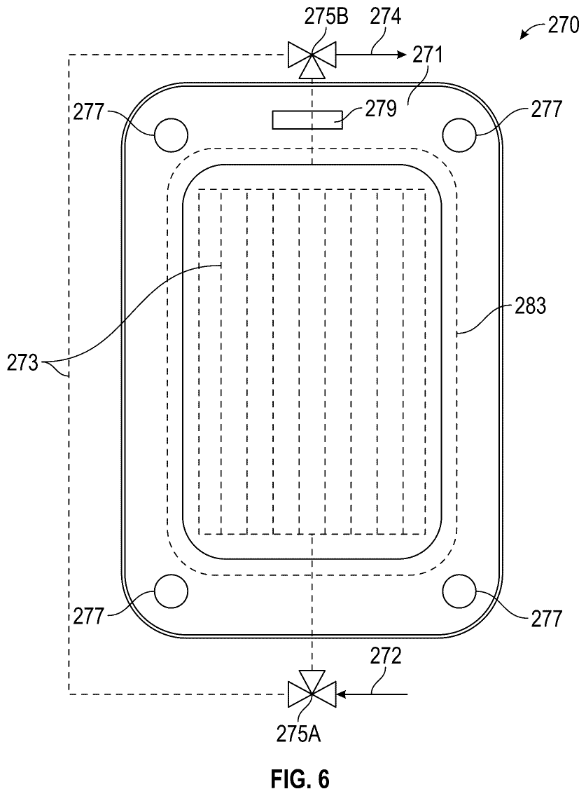

FIGS. 5-6 illustrate another example coolant block 270 in a housing 250. The coolant block 270 and housing 250 are similar to the coolant block 170 and housing 150, respectively, except where described below or shown in the FIGS. Similar or like components will include the addition of a leading “2”. The coolant block 270 includes a lid 271 that at least partially define internal cooling passages 273 with a portion of the housing 250 that extend between a cooling fluid inlet 272 and a cooling fluid outlet 274. A size of the internal cooling passages 273 can vary between different portions of the coolant block 270 to adjust and optimize for varying cooling needs across different portions of the coolant block 270.

In addition to the housing 250 being used to form a portion of the internal cooling passages 273 with the lid 271, a portion of the internal cooling passages 273 are routed through or adjacent to an internal dividing wall 258 to facilitate heat removal from the DC link capacitor 154 and its associated hardware, such as the first and second DC bus bars 164, 166. In one example, the cooling fluid passing through the internal cooling passages in the internal dividing wall 258 travels parallel to the cooling fluid traveling through the internal cooling passages 273 adjacent to the lid 271. A first valve 275A, such as a three-way valve, can direct the flow of cooling fluid from the cooling fluid inlet 272 through the internal cooling passages 273 by selectively bypassing or restricting the cooling fluid through the internal cooling passages 273 in the internal dividing wall 258 or adjacent to the lid 271. A second valve 275B, such as a three-way valve, can receive the cooling fluid from the internal cooling passages 273 and direct it to the cooling fluid outlet 274.

The lid 271 can be comprised of a metallic or composite material that facilitates the transfer of heat from the semiconductor switches 156 to the cooling fluid within the internal cooling passages 273. In the illustrated example, the lid 271 includes a switch engagement surface 271S for engaging the semiconductor switches 156. Furthermore, a thermal interface material, such as a thermal paste, can be placed between the semiconductor switches 156 and the switch engagement surface 271S to improve heat transfer therebetween.

In the illustrated example, the lid 271 is secured to the housing 250 using fasteners 277 that extend through the lid 271 and into fastener openings in the housing 250. As shown in FIGS. 5-6, at least one guide projection 279 is formed by the housing 250 and extends through a corresponding guide opening 281 on the lid 271 for aligning the lid 271 relative to the housing 250. Furthermore, as shown in FIG. 6, a seal 283 (shown in dashed lines) surrounds the internal cooling passages 273 and engages the lid 271 and the housing 250 to prevent cooling fluid in the internal cooling passages 273 from escaping.

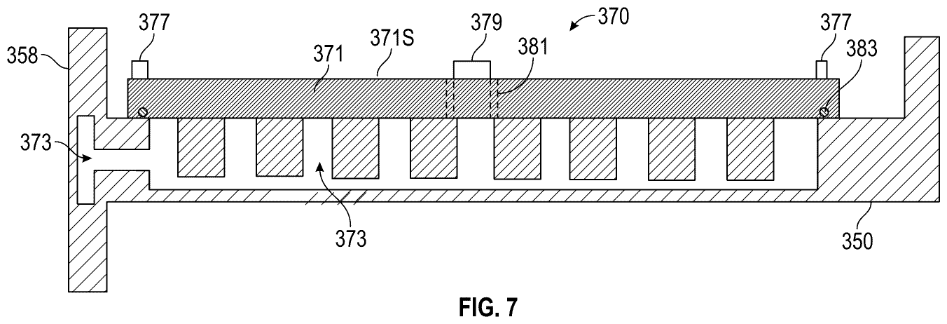

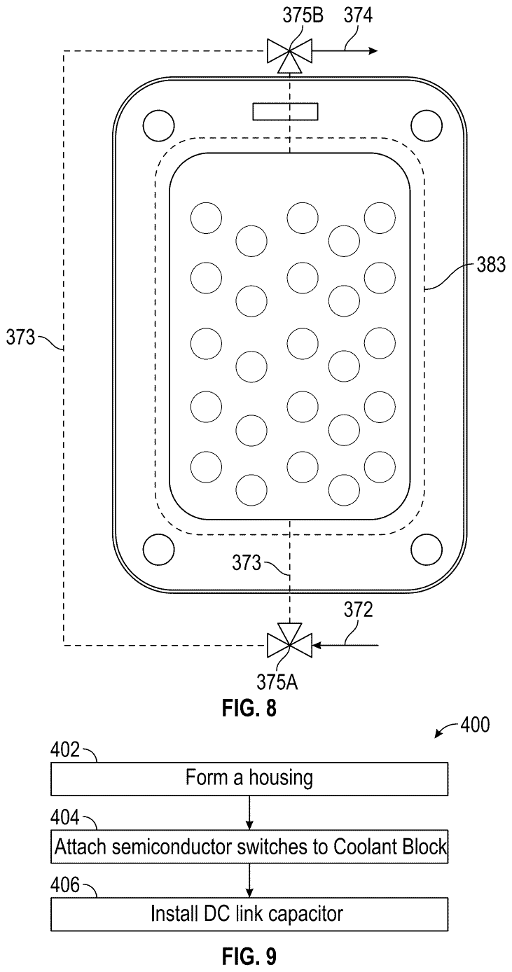

FIGS. 7-8 illustrate another example coolant block 370 in a housing 350. The coolant block 370 and housing 350 are similar to the coolant block 170 and housing 150, respectively, except where described below or shown in the FIGS. Similar or like components will include the addition of a leading “3”. The coolant block 370 includes a lid 371 that at least partially define internal cooling passages 373 with a portion of the housing 350 that extend between a cooling fluid inlet 372 and a cooling fluid outlet 374. A size of the internal cooling passages 373 can vary between different portions of the coolant block 370 to adjust and optimize for varying cooling needs across different portions of the coolant block 370.

In addition to the housing 350 being used to form a portion of the internal cooling passages 373 with the lid 371, a portion of the internal cooling passages 373 are routed through or adjacent to an internal dividing wall 358 to facilitate heat removal from the DC link capacitor 154 and its associated hardware, such as the first and second DC bus bars 164, 166. In one example, the cooling fluid passing through the internal cooling passages 373 in the internal dividing wall 358 can travel in parallel with the cooling fluid traveling adjacent to the lid 371. A first valve 375A, such as a three-way valve, can direct the flow of cooling fluid from the cooling fluid inlet 372 through the internal cooling passages 373 by selectively bypassing or restricting the cooling fluid through the internal cooling passages 373 in the internal dividing wall 358 or adjacent to the lid 371. A second valve 375B, such as a three-way valve, can receive the cooling fluid from the internal cooling passages 373 and direct it to the cooling fluid outlet 374.

The lid 371 can be comprised of a metallic or composite material that will facilitate the transfer of heat from the semiconductor switches 156 to the cooling fluid within the internal cooling passages 373. In the illustrated example, the lid 371 includes a switch engagement surface 371S for engaging the semiconductor switches 156. Furthermore, a thermal interface material, such as a thermal paste, can be placed between the semiconductor switches 156 and the switch engagement surface 371S to improve heat transfer therebetween.

The lid 371 is secured to the housing 350 using fasteners 377 that extend through the lid 371 and into fastener openings in the housing 350. At least one guide projection 379 is formed by housing 350 and extends through corresponding guide openings 381 (show in dashed lines in FIG. 7) on the lid 371 for aligning the lid 371 relative to the housing 350. Furthermore, a seal 383 (shown in dashed lines) surrounds the internal cooling passages 373 and engages the lid 371 and the housing 350 to prevent cooling fluid from in the internal cooling passages 373 from escaping.

FIG. 9 illustrates a method 400 of forming one of the PIM 128 described above. The method 400 begins at block 402 (“Form a Housing”), with forming a housing for the PIM 128. In one example, the housing 150, 250, 350 is formed from an injection molding process and is comprised of a resin, such as a polymer, and a fiber material to form a composite. A high voltage connector, such as the high-voltage DC connector 160, and a low-voltage connector, such as the communications connector 159, are formed integrally into the housing 150, 250, 350 to eliminate additional fasteners and assembly steps.

The coolant blocks 170, 270, 370 are at least partially fixed to the housing 150, 250, 350 while forming the housing 150, 250, 350. In one example, the coolant block 170 fully encloses the internal cooling passages itself and is over-molded into the housing 150. In another example, the housing 250, 350 at least partially defines internal cooling passages 273, 373 for the coolant block 270, 370, respectively, as shown in FIGS. 5-7. In this example, the lid 271, 371 at least partially defines the internal cooling passages 273, 373 and is secured to the housing 250, 350, respectively, after the housing 250, 350 is formed.

At block 404 (“Attach Semiconductor Switches to Coolant Block”), the semiconductor switches 156 are attached to one of the coolant blocks 170, 270, or 370. For the example of the coolant block 170, the semiconductor switches 156 can be attached to the coolant block 170 prior to the molding process that formed the housing 150 with the coolant block 170 over molded therein. Alternatively, the semiconductor switches 156 can be attached to the coolant block 170 after the coolant block 170 was over molded into the housing 150. For the coolant blocks 270 and 370, the semiconductor switches 156 can be attached to the lid 271, 371 of the coolant block 270, 370 prior to the lid 271, 371 being attached to the housing 250, 350, respectively, or after the lid 271, 371 is attached to the housing 250, 350.

The semiconductor switches 156 are in direct thermal engagement or contact with the coolant blocks 170, 270, 370. To improve the thermal contact between the semiconductor switches 156 and the coolant block 170, 270, 370, a thermal conductive material, such as a thermal paste, can be applied at the interface of the semiconductor switches 156 and the coolant block 170, 270, 370. The first DC bus bar 164 can then be connected to a corresponding one of the high switches and the second DC bus bar 166 can be connected to a corresponding one of the low switches. The AC bus bars 168 can then be attached to the semiconductor switches 156 for outputting alternating current from the PIM 128. Additionally, the AC bus bars 168 can pass through the choke 169 formed into the housing 150, 250, 350 as described above.

Additionally, forming the housing 150, 250, 350 can include forming the choke 169 integrally with the housing 150, 250, 350. The choke 169 is formed by over molding the nanocrystalline material with the housing material such that the choke 169 is integrally formed as a single piece with the housing 150, 250, 350. Once the housing 150, 250, 350 is formed, the method 400 then proceeds to block 406.

At block 406 (“Install DC Link Capacitor”), the DC link capacitor 154 is inserting into an internal cavity at least partially defined by the housing 150, 250, 350. The DC link capacitor 154 can be installed as a single unit with the pair of high-voltage DC bus bars 162 and the first and second DC bus bars 164, 166. Alternatively, the DC link capacitor, the pair of high-voltage DC bus bars 162, and the first and second DC bus bars 164, 166 can be installed separately. A potting material 155 can then be inserted into the housing 150, 250, 350 for securing and electrically isolating portions of the DC link capacitor 154 from the remainder of the PIM 128. With the DC link capacitor 154 and its associated components inserted, the method 400 ends. While the above method 400 describes an example flow diagram for forming the PIM 128, the order of installation or attachment of components into the housing 150, 250, 350 can vary depending on the application.

The PIM 128 can then be installed onto a driver assembly or other portion of the EV 111. While the PIM 128 is illustrated as an “open face” design that mates with another component on the EV 111 to be enclosed, the PIM 128 could include a separate lid for enclosing the internal cavity 152 that engages a seal 183.

The terms “a” and “an” do not denote a limitation of quantity, but rather denote the presence of at least one of the referenced items. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in a suitable manner in the various aspects.

While the above disclosure has been described with reference to exemplary embodiments, it will be understood by those skilled in the art that various changes may be made, and equivalents may be substituted for elements thereof without departing from its scope. In addition, many modifications may be made to adapt a particular situation or material to the teachings of the disclosure without departing from the scope thereof. Therefore, it is intended that the present disclosure not be limited to the particular embodiments disclosed but will include embodiments falling within the scope thereof.

What is claimed is:

1. An assembly comprising:
a housing comprised of a molded composite material, wherein the housing at least partially defines an internal cavity;
a coolant block fixed relative to the housing, wherein the coolant block includes a switch engagement surface facing into the internal cavity and at least one internal cooling passage extending between a cooling fluid inlet and a cooling fluid outlet;
a plurality of semiconductor switches located within the housing and in direct thermal engagement with the switch engagement surface on the coolant block, wherein the plurality of semiconductor switches are in electrical communication with a plurality of alternating current bus bars; and
a direct current link capacitor located within the internal cavity and in electrical communication with the plurality of semiconductor switches.

2. The assembly of claim 1, including a pair of high-voltage direct current bus bars in electrical communication with the direct current link capacitor and a high-voltage direct current connector integrally formed into the housing.

3. The assembly of claim 1, including at least one of a control board or a gate driver board located within the internal cavity and in electrical communication with a communications connector integrally formed into the housing and the plurality of semiconductor switches.

4. The assembly of claim 1, including a thermally conductive material located between the plurality of semiconductor switches and the coolant block.

5. The assembly of claim 1, wherein the housing includes an internal dividing wall at least partially separating the direct current link capacitor from the plurality of semiconductor switches and the direct current link capacitor is at least partially co-molded with the housing.

6. The assembly of claim 5, wherein the internal dividing wall includes a heat transfer feature embedded within the internal dividing wall and the heat transfer feature is in direct thermal engagement with the coolant block.

7. The assembly of claim 5, wherein a first direct current bus bar is in electrical communication with a first set of the plurality of semiconductor switches and a second direct current bus bar is in electrical communication with a second set of the plurality of semiconductor switches.

8. The assembly of claim 1, including a choke located within the internal cavity and defining a central opening that surrounds the plurality of alternating current bus bars in electrical communication with the plurality of semiconductor switches.

9. The assembly of claim 8, wherein the choke is over molded with the housing and includes a nanocrystalline material that forms a loop and surrounds the plurality of alternating current bus bars.

10. The assembly of claim 1, wherein the coolant block is comprised of a first material and the housing is comprised of a second material different from the first material and the housing at least partially surrounds a perimeter of the coolant block.

11. The assembly of claim 1, wherein coolant block includes internal cooling passages that are at least partially defined by the housing and a thermally conductive lid and the thermally conductive lid is in direct thermal contact with the plurality of semiconductor switches.

12. The assembly of claim 11, wherein the thermally conductive lid includes a plurality of heat transfer features extending therefrom that at least partially define the internal cooling passages.

13. A method of forming a power inverter module, the method comprising:
forming a housing for the power inverter module at least partially defining an internal cavity, wherein a coolant block is at least partially fixed relative to the housing while forming the housing and the coolant block includes a switch engagement surface facing into the internal cavity with at least one internal cooling passage extending between a cooling fluid inlet and a cooling fluid outlet;
attaching a plurality of semiconductor switches in direct thermal engagement with the coolant block; and
installing a direct current link capacitor in the internal cavity of the housing, wherein the plurality of semiconductor switches are in electrical communication with the direct current link capacitor and a plurality of alternating current bus bars.

14. The method of claim 13, wherein forming the housing includes forming a high-voltage direct current connector integrally into the housing for interfacing with high-voltage direct current bus bars in electrical communication with the direct current link capacitor and the direct current link capacitor is at least partially co-molded with the housing.

15. The method of claim 13, wherein forming the housing includes forming a choke having a nanocrystalline material that surrounds the plurality of alternating current bus bars integrally with the housing.

16. The method of claim 13, wherein the at least one internal cooling passage is spaced from the housing by a body portion of the coolant block.

17. The method of claim 13, wherein the at least one internal cooling passage is at least partially defined by the housing and a thermally conductive lid and the thermally conductive lid is in direct thermal contact with the plurality of semiconductor switches.

18. A vehicle comprising:
a vehicle body supported by a plurality of wheels;
a traction battery fixed relative to the vehicle body;
a traction motor in driving engagement with the plurality of wheels; and
a power inverter module electrically connecting the traction battery with the traction motor for selecting driving the plurality of wheels, wherein the power inverter module includes:
a housing comprised of a molded composite material, wherein the housing at least partially defines an internal cavity;
a coolant block fixed relative to the housing, wherein the coolant block includes a switch engagement surface facing into the internal cavity and at least one internal cooling passage extending between a cooling fluid inlet and a cooling fluid outlet;
a plurality of semiconductor switches located within the housing and in direct thermal engagement with the switch engagement surface on the coolant block, wherein the plurality of semiconductor switches are in electrical communication with a plurality of alternating current bus bars; and
a direct current link capacitor located within the internal cavity and in electrical communication with the plurality of semiconductor switches.

19. The vehicle of claim 18, including a pair of high-voltage direct current bus bars in electrical communication with the direct current link capacitor and a high-voltage direct current connector integrally formed into the housing with the direct current link capacitor at least partially co-molded with the housing.

20. The vehicle of claim 18, including at least one of a control board or a gate driver board located within the internal cavity and in electrical communication with a communications connector integrally formed into the housing and the plurality of semiconductor switches.
